(19) United States
(12) Patent Application Publication
(10) Pub. No.: US 2025/0344436 A1
(43) Pub. Date: Nov. 6, 2025

(54) Source/Drain Contacts And Methods For Forming The Same

(71) Applicant: Taiwan Semiconductor Manufacturing Company, Ltd., Hsin-Chu (TW)

(72) Inventors: Shahaji B. More, Hsinchu (TW); Cheng-Wei Chang, Hsinchu (TW)

(21) Appl. No.: 19/270,781

(22) Filed: Jul. 16, 2025

Related U.S. Application Data
(63) Continuation of application No. 18/182,144, filed on Mar. 10, 2023.
(60) Provisional application No. 63/389,187, filed on Jul. 14, 2022.
(60) Provisional application No. 63/419,386, filed on Oct. 26, 2022.

(51) Int. Cl. H10D 30/62; H10D 30/01; H10D 64/01; H10D 84/01; H10D 84/03; H10D 84/83

(52) U.S. Cl. CPC H10D 30/6219; H10D 30/024; H10D 30/6211; H10D 64/017; H10D 64/021; H10D 84/0128; H10D 84/013; H10D 84/0158; H10D 84/038; H10D 84/834

(57) ABSTRACT

Semiconductor structures and methods of forming the same are provided. In an embodiment, an exemplary method includes receiving a workpiece comprising a channel region over a substrate, a source/drain feature adjacent the channel region, a gate structure over the channel region, and a dielectric structure over the source/drain feature. The method also includes forming a contact opening penetrating through the dielectric structure to expose the source/drain feature, forming a silicide layer in the contact opening and on the source/drain feature, forming a tungsten-containing layer in the contact opening and on the silicide layer, and forming a conductive layer in the contact opening and on the tungsten-containing layer, where a composition of the conductive layer is different from a composition of the tungsten-containing layer.

### PRIORITY DATA

The present application is a continuation application of U.S. patent application Ser. No. 18/182,144, filed Mar. 10, 2023, which claims the benefit of U.S. Provisional Patent Application No. 63/389,187, filed on Jul. 14, 2022, and U.S. Provisional Patent Application No. 63/419,386 filed on Oct. 26, 2022, each of which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, parasitic resistance of source/drain contacts disposed over source/drain features may have serious bearings on the overall performance of an IC device. While existing source/drain contacts are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary workpiece to undergo various stages of operations in the method of FIG. 1, according to various aspects of the present disclosure.

FIGS. 3A, 4A, 5A, 6A, 7A, 8A, 9A, 10A, 11A, 12A, 13A, 14A, and 15A (FIGS. 3A-15A) illustrate fragmentary cross-sectional views of the workpiece taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B, and 15B (FIGS. 3B-15B) illustrate fragmentary cross-sectional views of the workpiece taken along line B-B′ as shown in FIG. 2 during various fabrication stages in the method of FIG. 1, according to one or more aspects of the present disclosure.

FIGS. 16A and 16B illustrates fragmentary cross-sectional views of a first alternative workpiece taken along line A-A′ and B-B′ as shown in FIG. 2, respectively, according to one or more aspects of the present disclosure.

FIGS. 17A and 17B illustrates fragmentary cross-sectional views of a second alternative workpiece taken along line A-A′ and B-B′ as shown in FIG. 2, respectively, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

To form source/drain features for a multi-gate device, source/drain regions of a fin-shaped active region (for a FinFET or an MBC transistor) are recessed. As used herein, a source/drain region, or “s/d region,” may refer to a source or a drain of a device. It may also refer to a region that provides a source and/or drain for multiple devices. After the recessing, multiple epitaxial layers are sequentially formed over the source/drain regions. Silicide layers and source/drain contacts may be then formed over the epitaxial layers of the source/drain features to provide electrical connection. During the formation of the source/drain contact, in some existing embodiments, the epitaxial layers of the source/drain feature may be recessed, and the source/drain contact may thus extend into the source/drain features, leading to a decreased landing area of the source/drain contacts and an increased resistance. In some existing embodiments, the source/drain contact formed by conventional fabrication processes may have one or more bubbles or voids trapped therein, which may increase the parasitic electrical resistance of the source/drain contacts and thus degrade the electrical performance of the IC device.

The present disclosure provides a method for forming semiconductor structures with reduced resistance. In an exemplary method, after forming the source/drain feature, a contact opening is formed. The formation of the contact opening slightly recesses the source/drain feature. A silicide layer is then formed in the contact opening. In the present embodiment, in a first cross-sectional view, the silicide layer has a substantially flat top surface, and in a second cross-sectional view, the silicide layer has a concave top surface. After forming the silicide layer, a tungsten layer formed by a physical vapor deposition (PVD) process is formed in the contact opening and on the silicide layer. In the first cross-sectional view, the tungsten layer has a substantially flat top surface, and in the second cross-sectional view, the tungsten layer has a convex top surface. The top surface of the tungsten layer is above a top surface of the source/drain feature. After forming the tungsten layer, a metal layer (e.g., cobalt, ruthenium, or molybdenum) formed by a chemical vapor deposition (CVD) process is formed in the contact opening and on the tungsten layer. The metal layer is spaced apart from the silicide layer by the tungsten layer. By forming the two-layer source/drain contact over a silicide layer that has a substantially flat top surface, the landing area of the source/drain contact and the contact area between the source/drain contact and the silicide layer may increase, thereby reducing the resistance and improving performance of the IC device.

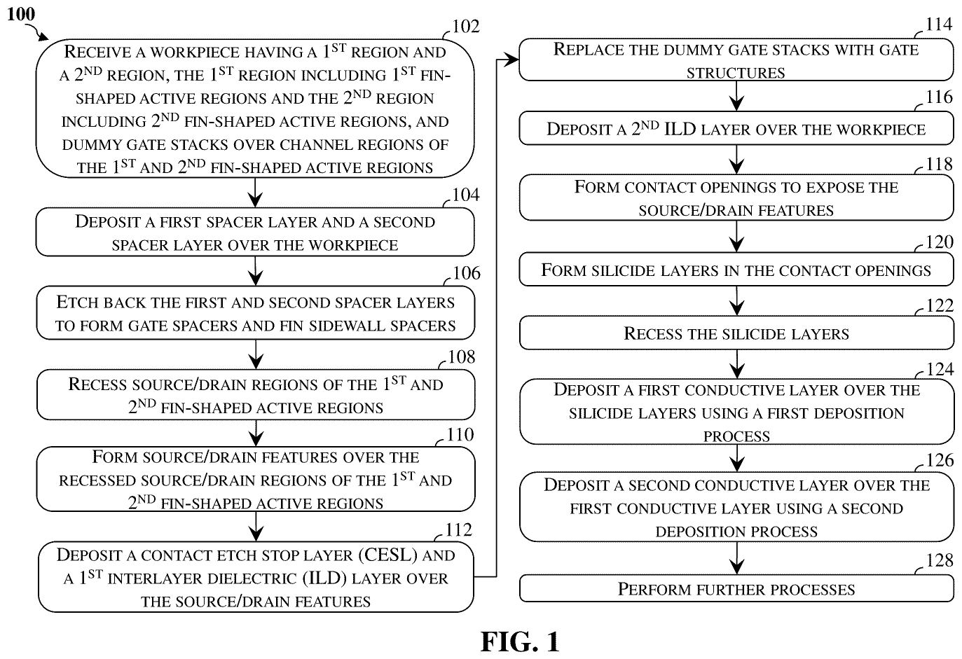

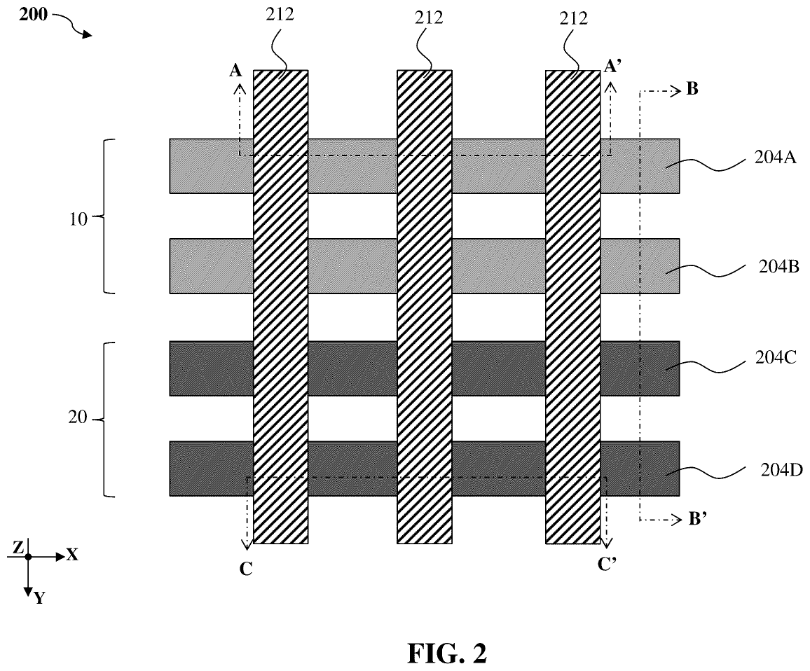

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2, 3A-17A and 3B-17B, which are fragmentary top/cross-sectional views of a workpiece 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the workpiece 200 will be fabricated into a semiconductor structure upon conclusion of the fabrication processes, the workpiece 200 may be referred to as the semiconductor structure 200 as the context requires. For avoidance of doubts, the X, Y and Z directions in FIGS. 2, 3A-17A, 3B-17B are perpendicular to one another and are used consistently throughout the present disclosure. Throughout the present disclosure, like reference numerals denote like features unless otherwise excepted.

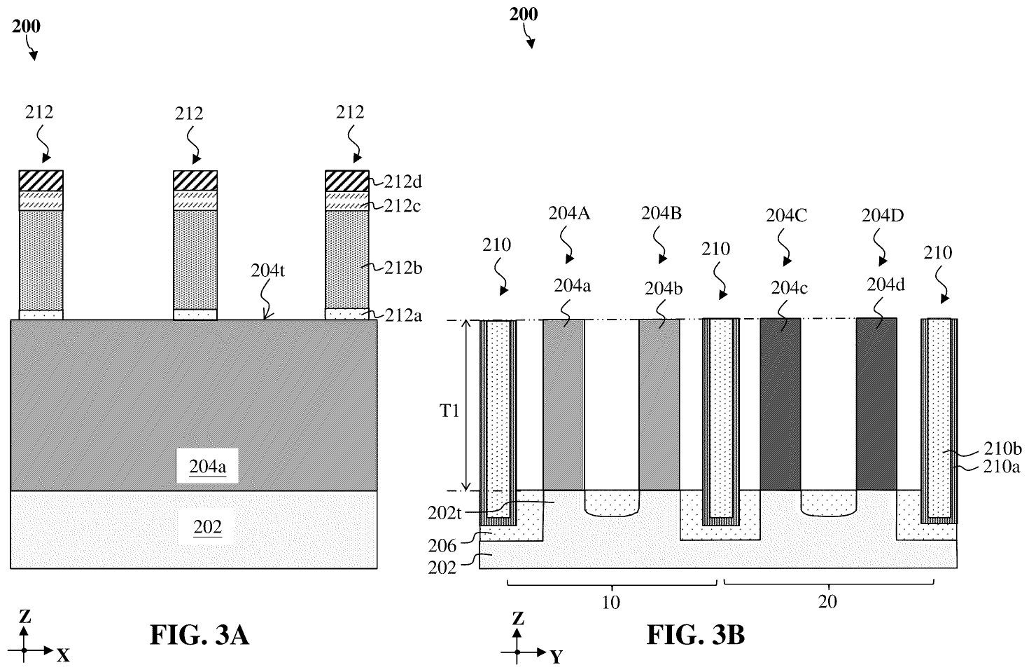

Referring to FIGS. 1, 2, and 3, method 100 includes a block 102 where a workpiece 200 that includes a first region 10 and a second region 20 is received. FIG. 2 depicts a fragmentary top view of a workpiece 200 to undergo various stages of operations in the method of FIG. 1, according to various aspects of the present disclosure. FIG. 3A illustrates a fragmentary cross-sectional view of the workpiece 200 taken along line A-A′ as shown in FIG. 2, and FIG. 3B illustrates a fragmentary cross-sectional view of the workpiece 200 taken along line B-B′ as shown in FIG. 2. Since a fragmentary cross-sectional view of the workpiece 200 taken along line C-C′ is similar to the fragmentary cross-sectional view of the workpiece 200 taken along line A-A′, the fragmentary cross-sectional view of the workpiece 200 taken along line C-C′ is omitted for reason of simplicity.

As illustrated in FIGS. 3A-3B, the workpiece 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); a non-semiconductor material, such as soda-lime glass, fused silica, fused quartz, and/or calcium fluoride (CaF2); and/or combinations thereof. In one embodiment, the substrate 202 is a silicon (Si) substrate. The substrate 202 may be uniform in composition or may include various layers, some of which may be selectively etched to form fin-shaped active regions (e.g., the fin-shaped active regions 204A-204D). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed on the substrate 202. In the embodiments represented in FIG. 2, a portion of the substrate 202 in the first region 10 is doped with an n-type dopant and a portion of the substrate 202 in the second region 20 is doped with a p-type dopant. The n-type dopant may include phosphorus (P) or arsenic (As). The p-type dopant may include boron (B), boron difluoride (BF₂), or indium (In). The n-type well and the p-type well may be formed using ion implantation or thermal diffusion and may be considered portions of the substrate 202. As will be described further below, the first region 10 is p-type field effect transistor (PFET) region for forming PFET(s) and the second region 20 is an n-type field effect transistor (NFET) region for forming NFET(s).

Still referring to FIGS. 2 and 3A-3B, the workpiece 200 includes a number of fin-shaped active regions (e.g., 204A, 204B, 204C, 204D) over the substrate 202. In the present embodiments, the first region 10 includes a fin-shaped active region 204A and a fin-shaped active region 204B extending vertically from the substrate 202, and the second region 20 includes a fin-shaped active region 204C and a fin-shaped active region 204D extending vertically from the substrate 202. The number of fin-shaped active regions depicted in FIGS. 2 and 3A-3B is just an example, the workpiece 200 may include any suitable number of active regions. Each of the fin-shaped active region 204A-204D may be formed from a corresponding semiconductor layer over the substrate 202 and a top portion 202t (shown in FIG. 3B) of the substrate 202 using a combination of lithography and etch steps. For example, in the present embodiments, to form the fin-shaped active regions 204A-204B in the first region 10 (e.g., PFET region) and the fin-shaped active region 204C-204D in the second region 20 (e.g., NFET region), a first semiconductor layer formed of silicon germanium (SiGe) is formed over the portion of the substrate 202 in the first region 10, and a second semiconductor layer formed of silicon (Si) is formed over the portion of the substrate 202 in the second region 20. The first semiconductor layer, the second semiconductor layer, and the top portion 202t of the substrate 202 are patterned to form the fin-shaped active regions 204A-204B in the first region 10 and the fin-shaped active region 204C-204D in the second region 20. An exemplary lithography process includes spin-on coating a photoresist layer, soft baking of the photoresist layer, mask aligning, exposing, post-exposure baking, developing the photoresist layer, rinsing, and drying (e.g., hard baking). In some instances, the patterning of the fin-shaped active regions 204A-204D may be performed using double-patterning or multi-patterning processes to create patterns having pitches smaller than what is otherwise obtainable using a single, direct photolithography process. The etching process can include dry etching, wet etching, and/or other suitable processes. In the present embodiments, FinFETs will be formed in the first region 10 and the second region 20. In some other implementations, GAA transistors may be formed in the first region 10 and the second region 20. In embodiments where GAA transistors are to be formed, instead of forming the corresponding semiconductor layer on the substrate 202, a vertical stack of alternating semiconductor layers that includes a number of channel layers interleaved by a number of sacrificial layers may be formed over the substrate 202. Each of the channel layers may be formed of silicon (Si) and each of the sacrificial layers may be formed of silicon germanium (SiGe).

As depicted in FIG. 2 and FIG. 3B, each of the fin-shaped active regions 204A-204D extends lengthwise along the X direction and are spaced apart from one another along the Y direction by portions of an isolation feature 206 (shown in FIG. 3B). The isolation feature 206 may also be referred to as a shallow trench isolation (STI) feature 206. In an example process, a dielectric material for the isolation feature 206 is first deposited over the workpiece 200, filling the trenches between the fin-shaped active regions 204A-204D with the dielectric material. In some embodiments, the dielectric material may include silicon oxide, silicon oxynitride, fluorine-doped silicate glass (FSG), a low-k dielectric, combinations thereof, and/or other suitable materials. In various examples, the dielectric material may be deposited by a CVD process, a flowable CVD (FCVD) process, spin-on coating, and/or other suitable process. The deposited dielectric material is then thinned and planarized, for example by a chemical mechanical polishing (CMP) process, until top surfaces of the fin-shaped active regions 204A-204D are exposed. The planarized dielectric material is further recessed or etched back by a dry etching process, a wet etching process, and/or a combination thereof to form the isolation feature 206. In some embodiments represented in FIG. 3B, upper portions 204a-204d of the fin-shaped active regions 204A-204D rise above the isolation feature 206 while lower portions (formed from the top portion 202t of the substrate 202) of the fin-shaped active regions 204A-204D remain covered or buried in the isolation feature 206. In an embodiment, a height T1 of each of the upper portions 204a-204d may be between about 30 nm and about 80 nm. In an embodiment, top surfaces of the upper portions 204a-204d are coplanar. The top surface of the upper portion 204a/204b/204c/204d (i.e., the top surface of the fin-shaped active region 204A/204B/204C/204D) is referred to as top surface 204t. In the present embodiment, the upper portions 204a-204b are formed of silicon germanium, and the upper portions 204c-204d are formed of silicon. In the present embodiments, the fin-shaped active regions 204A and the 204B will serve as a dual-fin active region for a dual-fin device in the first region 10. The fin-shaped active regions 204C and 204D will serve as dual-fin device in the second region 20. The present disclosure is also applicable to single-fin devices or other multi-fin devices.

The workpiece 200 also includes hybrid fins 210 extending into the isolation feature 206. In embodiments represented in FIG. 3B, hybrid fins 210 are formed to isolate subsequently formed source/drain features (e.g., source/drain features 222P and 222N). The hybrid fins 210 may be formed along with the isolation feature 206 and may include an outer layer 210a and an inner layer 210b. In an example process, the dielectric material for the isolation feature 206 is first conformally deposited over the workpiece 200. Thereafter, the outer layer 210a and the inner layer 210b are sequentially deposited over the workpiece 200. After the planarization process, only the dielectric layer for the isolation feature 206 is selectively etched back to form the isolation feature 206. Because of the selective nature, the etching back also leaves behind the hybrid fins 210. Because the dielectric material for the isolation feature 206 substantially fills the space between the fin-shaped active region 204A and the fin-shaped active region 202B as well as between the fin-shaped active region 204C and the fin-shaped active region 204D, hybrid fins 210 are not formed between the fins in the dual-fin active regions. The hybrid fins 210 may also be referred to as dielectric fins 210 as they are formed of dielectric materials. In an embodiment, the outer layer 210a may include silicon oxycarbonitride (SiOCN), and the inner layer 210b may also include silicon oxycarbonitride (SiOCN), and a carbon concentration of the outer layer 210a is greater than a carbon concentration of the inner layer 210b. As shown in FIG. 3B, each of the hybrid fins 210 extends into the isolation feature 206 and is spaced apart from the lower portions of the fin-shaped active regions 204A-204D or the substrate 202 by the isolation feature 206.

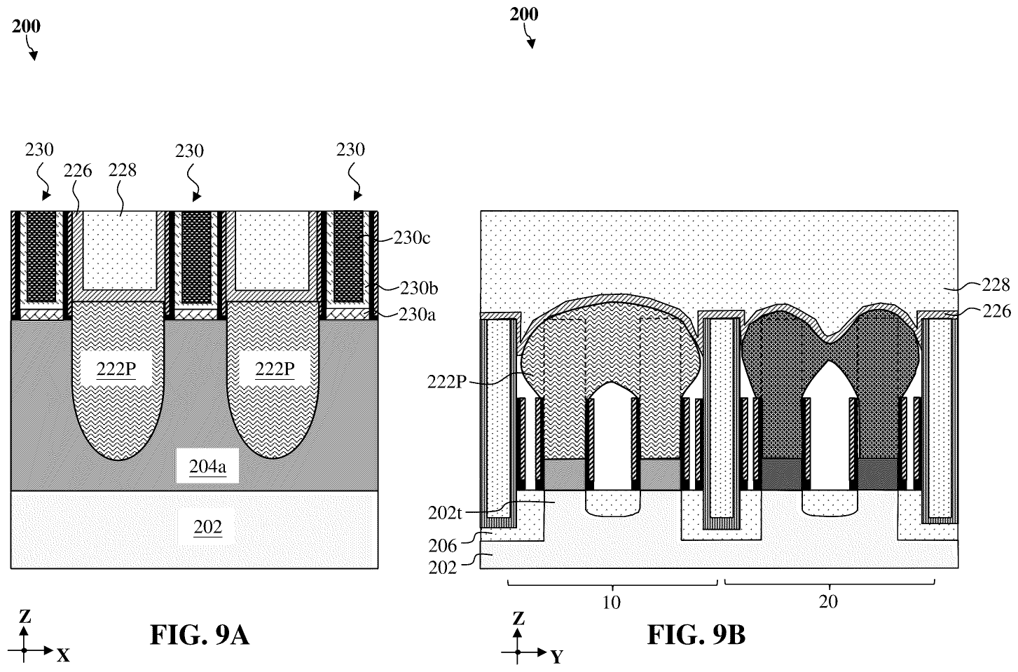

The fin-shaped active region 204 extends lengthwise along the X direction and is divided into channel regions overlapped by dummy gate stacks 212 (to be described below) and source/drain regions not overlapped by the dummy gate stacks 212. Source/drain region(s) may refer to a source region or a drain region, individually or collectively dependent upon the context. Each of the channel regions is disposed between two source/drain regions along the X direction. Three dummy gate stacks 212 are shown in FIG. 2 and FIG. 3A, but the workpiece 200 may include any suitable number of dummy gate stacks 212. In this embodiment, a gate replacement process (or gate-last process) is adopted where the dummy gate stacks 212 serve as placeholders for functional gate structures (e.g., gate structures 230 shown in FIG. 9A). Other processes and configurations are possible. The dummy gate stack 212 includes a dummy gate dielectric layer 212a, a dummy gate electrode layer 212b over the dummy gate dielectric layer 212a, a first gate-top hard mask layer 212c over the dummy gate electrode layer 212b, and a second gate-top hard mask layer 212d over the first gate-top hard mask layer 212c. The dummy gate dielectric layer 212a may include silicon oxide. The dummy gate electrode layer 212b may include polysilicon. The first gate-top hard mask layer 212c and the second gate-top hard mask layer 212d may include silicon oxide layer, silicon nitride, and/or other suitable materials. Suitable deposition process, photolithography and etching process may be employed to form the dummy gate stack 212.

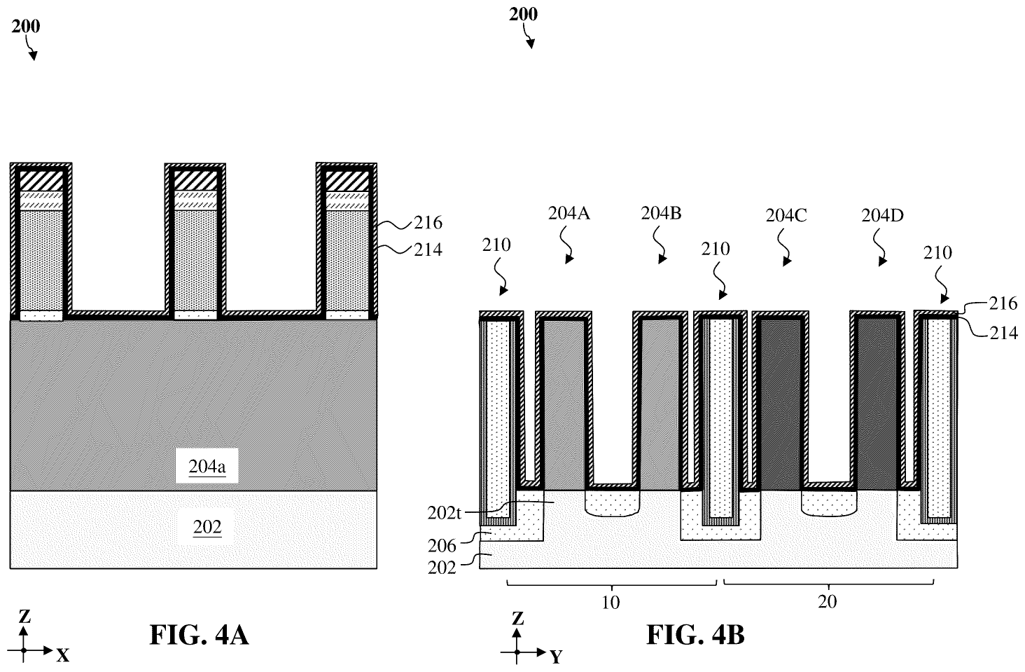

Referring to FIGS. 1 and 4A-4B, method 100 includes a block 104 where a first spacer layer 214 is conformally deposited over the workpiece 200 and a second spacer layer 216 is conformally deposited over the first spacer layer 214. The first spacer layer 214 is conformally deposited over the workpiece 200, including the fin-shaped active region 204A-204D and the hybrid fins 210, by ALD, CVD, or any other suitable deposition process. The term “conformally” may be used herein for case of description of a layer having substantially uniform thickness over various regions of the workpiece 200. The first spacer layer 214 may include silicon oxide, silicon nitride, silicon oxycarbide, silicon oxycarbonitride, silicon carbonitride, metal nitride, or other suitable dielectric materials. In an embodiment, the first spacer layer 214 includes silicon carbonitride (SiCN). After forming the first spacer layer 214, the second spacer layer 216 is conformally deposited over the first spacer layer 214 by ALD, CVD, or any other suitable deposition process. The second spacer layer 216 may include silicon oxide, silicon nitride, silicon oxycarbide, silicon oxycarbonitride, silicon carbonitride, metal nitride, or other suitable dielectric materials. A composition of the first spacer layer 214 is different from a composition of the second spacer layer 216 to introduce etching selectivity. In an embodiment, the second spacer layer 216 includes silicon nitride (SiN).

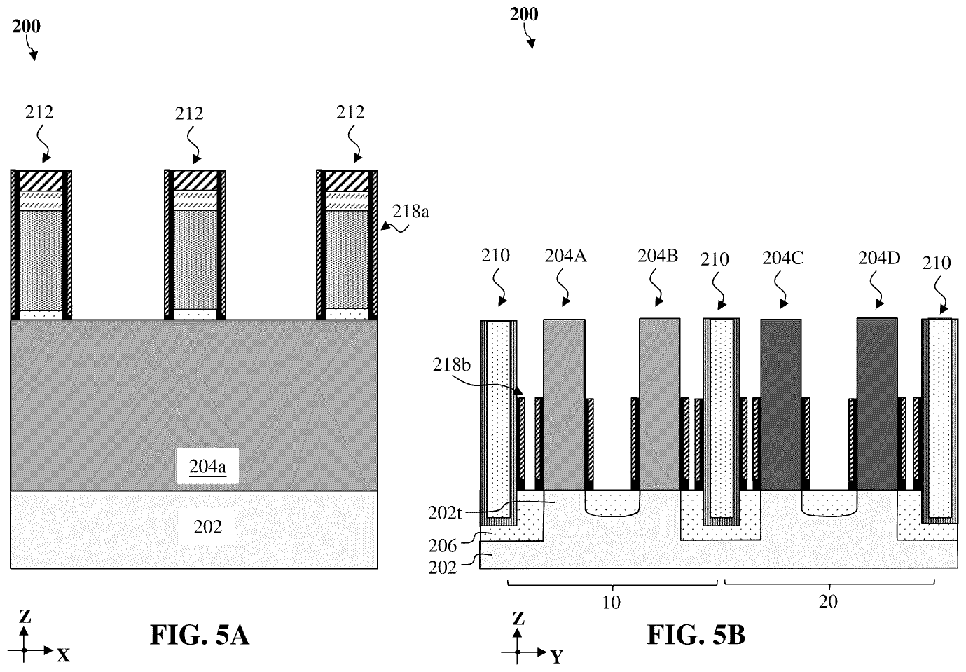

Referring to FIGS. 1 and 5A-5B, method 100 includes a block 106 where the first spacer layer 214 and the second spacer layer 216 are etched back to form gate spacers 218a and fin sidewall spacers 218b. After the formation of the first spacer layer 214 and the second spacer layer 216, an etching process is performed to remove portions of the first spacer layer 214 and the second spacer layer 216 over top-facing surfaces of the workpiece 200 to form gate spacers 218a extending along sidewalls of the dummy gate stacks 212 and fin sidewall spacers 218b extending along lower portions of sidewalls of the fin-shaped active regions 204A-204D and the dielectric fins 210. In some other embodiments, each of the gate spacers 218a and fin sidewall spacers 218b may be a single-layer structure that is formed of one spacer layer.

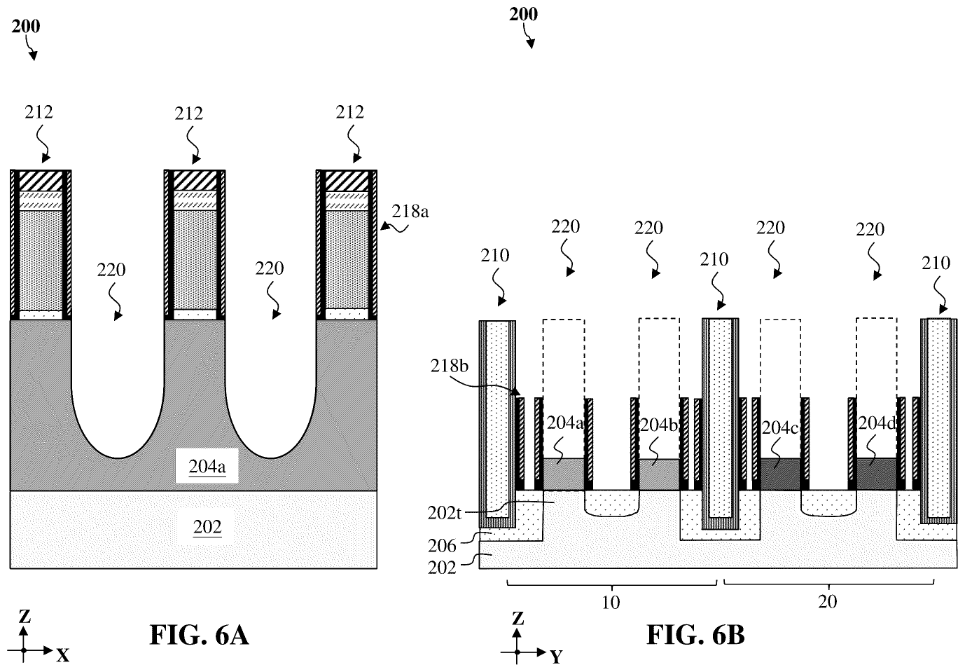

Referring to FIGS. 1 and 6A-6B, method 100 includes a block 108 where source/drain regions of the fin-shaped active regions 204A-204D are recessed to form source/drain openings 220. In some embodiments, the source/drain regions of the fin-shaped active regions 204A-204D are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In the present embodiments, the upper portions 204a-204d of the fin-shaped active regions 204A-204D that rise above the isolation feature 206 are recessed to form the source/drain openings 220. In an embodiment, top surfaces of the recessed upper portions 204a-204d are below top surfaces of the fin sidewall spacers 218b.

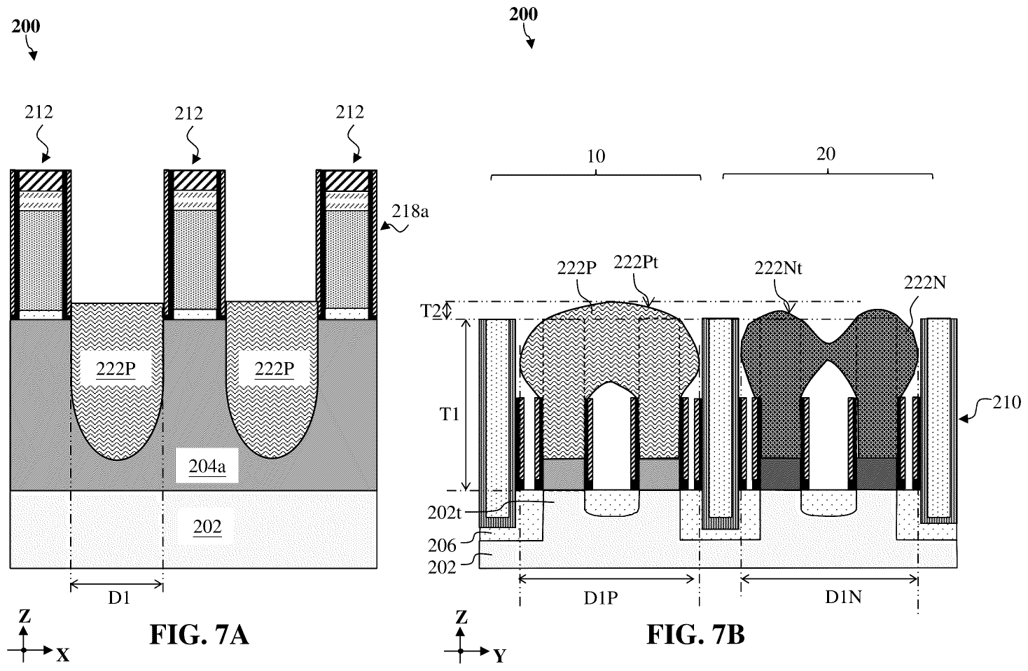

Referring to FIGS. 1 and 7A-7B, method 100 includes a block 110 where source/drain features are formed in the source/drain openings 220. Source/drain feature(s) may refer to a source feature or a drain feature, individually or collectively dependent upon the context. Depending on the conductivity type of the to-be-formed transistor, the source/drain features may be n-type source/drain features or p-type source/drain features. In the present embodiments, n-type source/drain feature 222N is formed in source/drain opening 220 in the second region 20 and over the recessed upper portions 204c-204d of the fin-shaped active regions 204C-204D, and p-type source/drain feature 222P is formed in source/drain opening 220 in the first region 10 and over the recessed upper portions 204a-204b of the fin-shaped active regions 204A-204B. It can be seen that the hybrid fins 210 function to keep adjacent source/drain features separated from one another.

The p-type source/drain feature 222P in the first region 10 and the n-type source/drain feature 222N in the second region 20 have different compositions and are formed separately. The p-type source/drain feature 222P may include silicon germanium (SiGe) or other semiconductor composition with good hole mobility and are doped with at least one p-type dopant, such as boron (B), boron difluoride (BF₂), or indium (In). The n-type source/drain feature 222N may include silicon (Si) or other semiconductor composition with good electron mobility and are doped with at least one n-type dopant, such as phosphorus (P) or arsenic (As). In one example process, a first mask layer is first deposited to cover the second region 20 and epitaxial deposition processes are performed to form the p-type source/drain feature 222P in the first region 10. The first mask layer is then removed. A second mask layer is deposited to cover the first region 10 and epitaxial deposition processes are performed to form the n-type source/drain feature 222N in the second region 20.

The p-type source/drain feature 222P may include multiple epitaxial layers. The multiple epitaxial layers of the p-type source/drain feature 222P may be deposited using a suitable technique, such as vapor-phase epitaxy (VPE), ultra-high vacuum CVD (UHV-CVD), a reduced pressure CVD, a cyclic deposition and etching (CDE) process, molecular beam epitaxy (MBE), and/or other suitable processes. The process temperature may be between about 600° C. and about 700° C. To form p-type source/drain feature 222P that includes silicon germanium (SiGe), the epitaxial deposition may include use of silane (SiH₄), dichlorosilane (Si₂H₂Cl₂), germane (GeH₄), and hydrogen (H₂). One or more of the multiple epitaxial layers may be in-situ doped with the p-type dopant using, for example, diborane (B₂H₆). In an embodiment, the p-type source/drain feature 222P includes a first epitaxial layer and a second epitaxial layer over the first epitaxial layer, both the first epitaxial layer and the second epitaxial layer includes SiGe, and each of a germanium content of the first epitaxial layer and a germanium content of the second epitaxial layer is between 25% and about 60% and each of a boron (B) concentration of the first epitaxial layer and a boron concentration of the second epitaxial layer is between about 1×10²⁰ atoms/cm³ and about 3×10²¹ atoms/cm³. In an embodiment, the boron concentration of the first epitaxial layer is less than the boron concentration of the second epitaxial layer.

The n-type source/drain feature 222N may include multiple epitaxial layers. The multiple epitaxial layers of the n-type source/drain feature 222N may be deposited using a suitable technique, such as vapor-phase epitaxy (VPE), ultra-high vacuum CVD (UHV-CVD), a reduced pressure CVD, a cyclic deposition and etching (CDE) process, molecular beam epitaxy (MBE), and/or other suitable processes. The process temperature may be between about 600° C. and about 700° C. To form the n-type source/drain feature 222N that includes silicon (Si), the epitaxial deposition may include use of silane (SiH₄), dichlorosilane (Si₂H₂Cl₂), and hydrogen (H₂). One or more of the multiple epitaxial layers may be in-situ doped with the n-type dopant using, for example, phosphine (PH₃) or arsine (AsH₃). In an embodiment, the n-type source/drain features 222N includes a first epitaxial layer and a second epitaxial layer over the first epitaxial layer, both the first epitaxial layer and the second epitaxial layer includes Si, and each of a phosphorus (P) concentration of the first epitaxial layer and a phosphorus concentration of the second epitaxial layer is between about 1×10²⁰ atoms/cm³ and about 4×10²¹ atoms/cm³. In an embodiment, the phosphorus concentration of the first epitaxial layer is less than the phosphorus concentration of the second epitaxial layer. In the cross-sectional view of the workpiece 200 shown in FIG. 7A, the p-type source/drain feature 222P spans a width D1 along the X direction. In an embodiment, the width D1 may be between about 20 nm and about 30 nm. In a cross-sectional view taken along line C-C′, the n-type source/drain feature 222N may span a width that is equal to the width D1.

Reference is made to FIG. 7B. During the formation of the p-type source/drain feature 222P, the epitaxial layer(s) of the p-type source/drain feature 222P merges and forms the p-type source/drain feature 222P having a substantially flat top surface 222 Pt. The topmost point of the substantially flat top surface 222 Pt is above the top surface 204t of the fin-shaped active region 204A/204B. A distance between the topmost point of the substantially flat top surface 222 Pt and the top surface 204t of the fin-shaped active region 204A/204B may be referred to as a raise height T2. In an embodiment, the raise height T2 of the p-type source/drain feature 222P may be between about 1 nm and about 10 nm. A raise height of the n-type source/drain feature 222N may also be between about 1 nm and about 10 nm. In an embodiment, the raise height T2 of the p-type source/drain feature 222P is greater than the raise height of the n-type source/drain feature 222N. During the formation of the n-type source/drain feature 222N, the epitaxial layer(s) of the n-type source/drain feature 222N merges and forms the n-type source/drain feature 222N having a wavy and concave top surface 222Nt. The topmost point of the wavy and concave top surface 222Nt is above a top surface of the fin-shaped active region 204A/204B. The n-type source/drain feature 222N spans a width D1N along the Y direction. In an embodiment, the width D1N may be between about 60 nm and about 70 nm. The p-type source/drain feature 222P spans a width D1P along the Y direction. The width D1P may be less than the width D1N. In an embodiment, the width D1P is greater than D1 and may be between about 55 nm and about 65 nm.

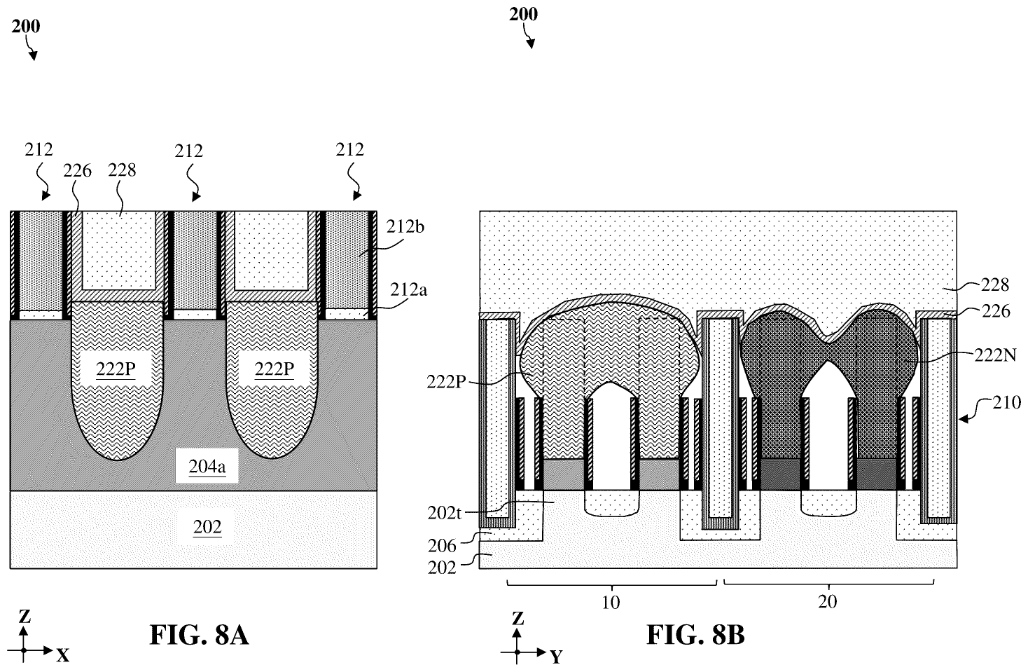

Referring to FIGS. 1 and 8A-8B, method 100 includes a block 112 where a contact etch stop layer (CESL) 226 and a first interlayer dielectric (ILD) layer 228 are deposited over the workpiece 200. The CESL 226 may include silicon nitride, silicon oxynitride, and/or other suitable materials and may be formed by ALD, plasma-enhanced chemical vapor deposition (PECVD) process and/or other suitable deposition or oxidation processes. The first ILD layer 228 is deposited by a PECVD process or other suitable deposition technique over the workpiece 200 after the deposition of the CESL 226. The first ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the workpiece 200 to remove excess materials and expose top surfaces of the dummy gate electrode layers 212b in the dummy gate stacks 212.

Referring to FIGS. 1 and 9A-9B, method 100 includes a block 114 where the dummy gate stacks 212 are replaced by gate structures 230. With the exposure of the dummy gate electrode layers 212b, the dummy gate stacks 212 are selectively removed. The removal of the dummy gate stacks 212 may include one or more etching process selective to the materials in the dummy gate stacks 212. For example, the removal of the dummy gate stacks 212 may be performed using a selective wet etch, a selective dry etch, or a combination thereof. In embodiments represented in FIG. 9A, after the removal of the dummy gate stacks 212, gate structures 230 are formed. Each of the gate structures 230 may include a gate dielectric layer and a gate electrode layer 230c over the gate dielectric layer. In some embodiments, the gate dielectric layer includes an interfacial layer 230a disposed over the substrate 202 and a high-k dielectric layer 230b over the interfacial layer 230a. In some embodiments, the interfacial layer 230a includes silicon oxide. The high-k dielectric layer 230b is then deposited over the interfacial layer using ALD, CVD, and/or other suitable methods. Here, a high-k dielectric layer 230b refers to a dielectric material having a dielectric constant greater than that of silicon dioxide, which is about 3.9. The high-k dielectric layer 230b may include hafnium oxide. Alternatively, the high-k dielectric layer 230b may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer 230c is then deposited over the gate dielectric layer using atomic layer deposition (ALD), physical vapor deposition (PVD), chemical vapor deposition (CVD), e-beam evaporation, or other suitable methods. The gate electrode layer 230c may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 230c may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. In some embodiments, different gate electrode layers 230c may be formed separately for n-type transistors and p-type transistors, which may include different work function metal layers (e.g., for providing different n-type and p-type work function metal layers).

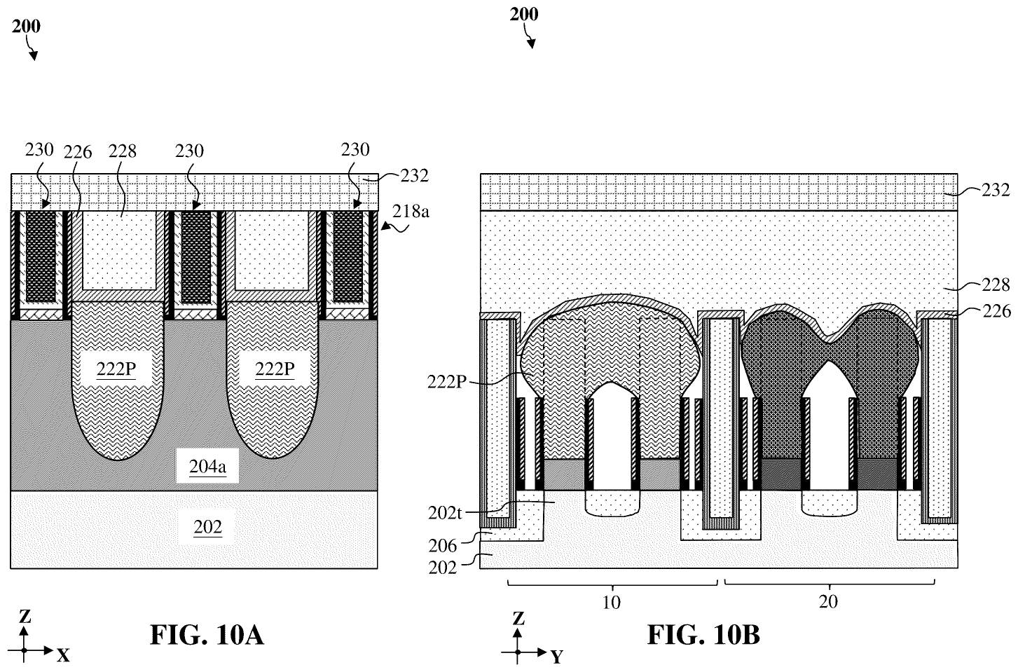

Referring to FIGS. 1 and 10A-10B, method 100 includes a block 116 where a second ILD layer 232 is deposited over the workpiece 200. The second ILD layer 232 may be similar to the first ILD layer 228 in terms of composition and formation processes. The second ILD layer 232 may be deposited using CVD, FCVD, spin-on coating, or a suitable deposition method. The second ILD layer 232 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

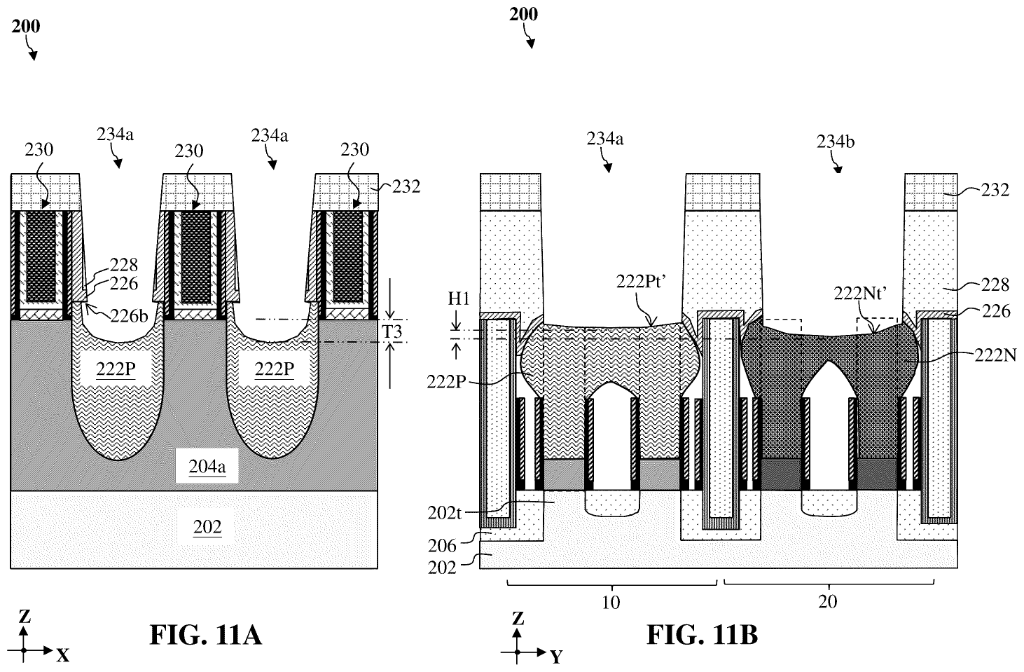

Referring to FIGS. 1 and 11A-11B, method 100 includes a block 118 where a first contact opening 234a is formed to expose the p-type source/drain feature 222P and a second contact opening 234b is formed to expose the n-type source/drain feature 222N. The contact openings 234a and 234b penetrate through the second ILD layer 232, the first ILD layer 228, and the CESL 226 using a combination of photolithography processes and etch processes. In an example process, a hard mask layer and a photoresist are deposited over the workpiece 200. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. The patterned hard mask layer is then applied as an etch mask to etch the second ILD layer 232, the first ILD layer 228, and the CESL 226. The etch process for etching the second ILD layer 232, the first ILD layer 228, and the CESL 226 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

The etch process further recesses p-type source/drain feature 222P and the n-type source/drain feature 222N. Due to different etch characteristics and different shapes of the p-type source/drain feature 222P and the n-type source/drain feature 222N, after the performing of the etch process, the first contact opening 234a and the second contact opening 234b have different shapes. More specifically, since the p-type source/drain feature 222P has the substantially flat top surface 222 Pt and the n-type source/drain feature 222N has the concave and wavy shape top surface 222Nt, the first contact opening 234a has a first depth that is less than a second depth of the second contact opening 234b. In an embodiment, a depth difference H1 between the first depth and the second depth is greater than 1 nm. Since the p-type source/drain feature 222P has the substantially flat top surface 222 Pt and the n-type source/drain feature 222N has the concave and wavy shape top surface 222Nt, as depicted in FIG. 11B, after the etch process, the recessed p-type source/drain feature 222P has a substantially flat top surface 222 Pt′ and the recessed n-type source/drain feature 222N has the concave and wavy shape top surface 222Nt′. In embodiments represented in FIG. 11A, a distance T3 between a bottommost point of the recessed top surface 222 Pt′ and the top surface 204t of the fin-shaped active region 204A/204B is between about 10 nm and about 15 nm. In embodiments represented in FIG. 11A, the second contact opening 234a exposes a portion 226b of a bottom surface and a portion of a sidewall surface of the CESL 226, and further exposes a portion of a sidewall surface of the first ILD layer 228. That is, the CESL 226 overhangs the recessed p-type source/drain feature 222P.

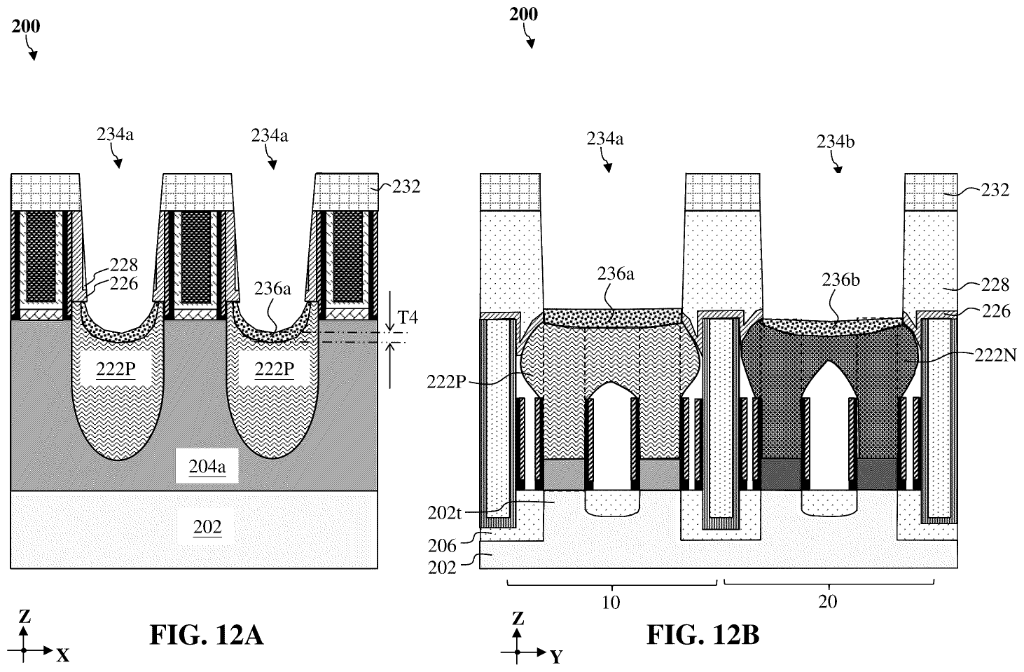

Referring to FIGS. 1 and 12A-12B, method 100 includes a block 120 where a silicide layer 236a and a silicide layer 236b are formed in the first contact opening 234a and the second contact opening 234b, respectively. To reduce contact resistance, a silicide layer 236a is formed on the recessed p-type source/drain feature 222P and a silicide layer 236b is formed on the recessed n-type source/drain feature 222N. To form the silicide layer 236a and the silicide layer 236b, a metal precursor, such as titanium (Ti), is deposited over the exposed surface of the recessed n-type source/drain feature 222N and the exposed surface of the recessed p-type source/drain feature 222P. An anneal process is then performed to bring about silicidation (and germinidation in the first region 10) between the metal precursor and the exposed semiconductor surfaces. In the depicted embodiments, titanium may react with silicon germanium in the p-type source/drain feature 222P to form the silicide layer 236a and may react with silicon in the n-type source/drain feature 222N to form the silicide layer 236b. In some embodiments, the unreacted metal precursor is selectively removed after the formation of the silicide layers 236a and 236b. During the removal of the unreacted metal precursor, the silicide layers 236a/236b may be partially oxidized. In the present embodiments, the silicide layer 236a is formed simultaneously with the silicide layer 236b. In some other embodiments, the silicide layer 236a and the silicide layer 236b may be formed in any suitable sequential order.

In the present embodiment, in a cross-sectional view depicted in FIG. 12B, since the recessed p-type source/drain feature 222P has a substantially top surface 222 Pt′, the silicide layer 236a formed on the recessed p-type source/drain feature 222P has a substantially uniform thickness, and a top surface of the silicide layer 236a is substantially flat. Since the recessed n-type source/drain feature 222N has the concave and wavy shape top surface 222Nt′, the silicide layer 236b formed on the recessed n-type source/drain feature 222N has a substantially flat top surface and a non-uniform thickness. More specifically, the silicide layer 236b is thicker in the middle and is thinner proximate to its edge. In a cross-sectional view depicted in FIG. 12A, a thickness T4 of the silicide layer 236a is between about 5 nm and about 10 nm. In a cross-sectional view depicted in FIG. 12A, a top surface of the silicide layer 236b has a concave surface.

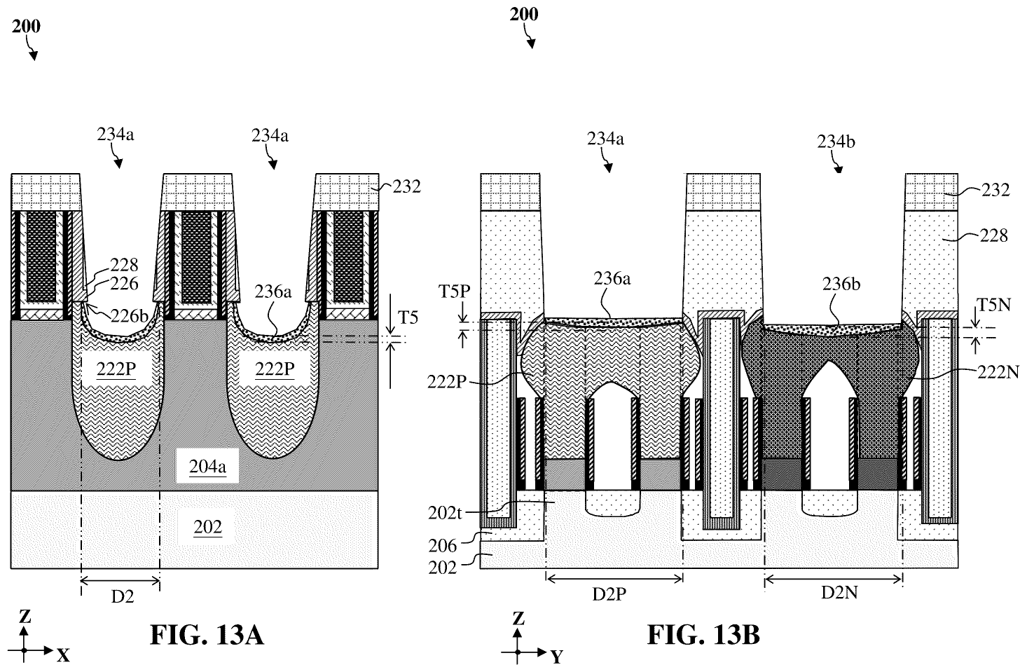

Referring to FIGS. 1 and 13A-13B, method 100 includes a block 122 where the silicide layers 236a and 236b are recessed. In the present embodiments, after forming the silicide layers 236a and 236b, the silicide layers 236a and 236b are recessed to remove oxidized portions of the silicide layers. In an embodiment, after the recessing, a thickness T5 of the silicide layer 236a in the cross-sectional view of the workpiece 200 taken along line A-A′ is between about 3 nm and about 5 nm. As depicted in FIG. 13A, the recessed silicide layer 236a spans a width D2 along the X direction. The width D2 may be between about 15 nm and about 20 nm. In embodiments represented in FIG. 13B, the silicide layer 236b spans a width D2N along the Y direction. The width D2N is greater than the width D2. In an embodiment, the width D2N may be between about 40 nm and about 50 nm. The silicide layer 236a spans a width D2P along the Y direction. The width D2P is greater than the width D2. In an embodiment, the width D2P may be between about 35 nm and about 45 nm.

As depicted in FIG. 13B, the recessed silicide layer 236a has a thickness T5P. The thickness T5P is greater than the thickness T5 and may be between about 5 nm and about 10 nm. In an embodiment, a thickness difference between the thickness T5P and the thickness T5 is between about 2 nm and about 5 nm. The recessed silicide layer 236b is thicker in the middle and is thinner proximate to its edge and has a thickness T5N in the middle. The thickness T5N is greater than the thickness T5 and may be between about 5 nm and about 10 nm. In an embodiment, a thickness difference between the thickness T5N and the thickness T5 is between about 2 nm and about 5 nm. The recessed silicide layer 236a and the recessed silicide layer 236b each have a substantially flat top surface. Forming the flat top surfaces would reduce step coverage of metal formed thereover and reduce contact resistance.

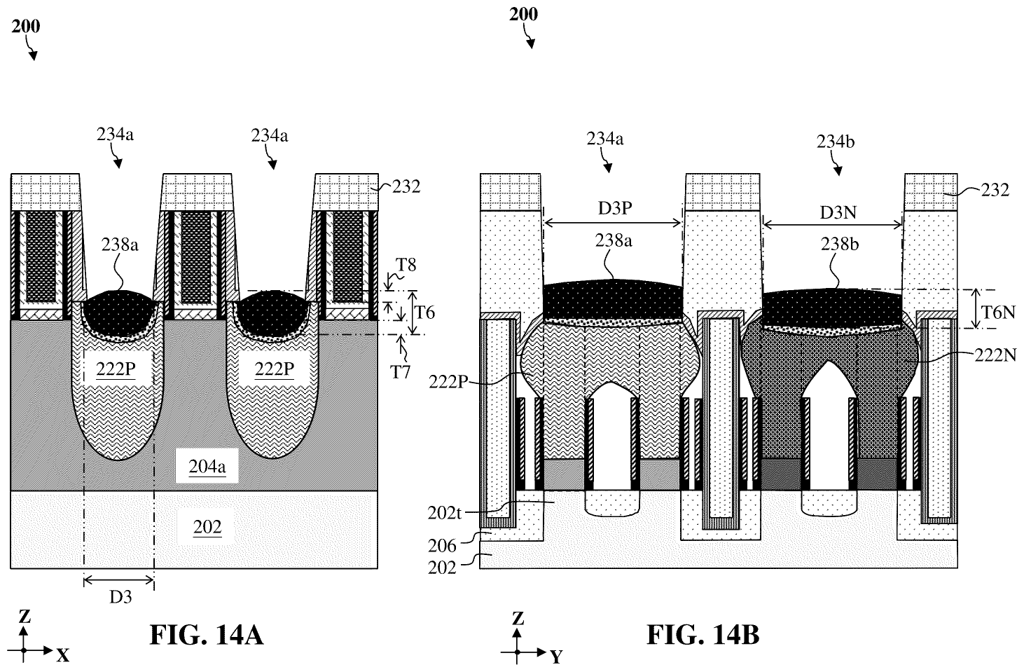

Referring to FIGS. 1 and 14A-14B, method 100 includes a block 124 where a first conductive layer 238a is formed in the first contact opening 234a and a second conductive layer 238b is formed in the second contact opening 234b. In an embodiment, the first conductive layer 238a and the second conductive layer 238b are formed by a same physical vapor deposition (PVD) process. That is, a composition and a thickness of the first conductive layer 238a are the same as a composition and a thickness of the second conductive layer 238b. In an embodiment, the first conductive layer 238a and the second conductive layer 238b includes tungsten (W). Implementing the PVD process may advantageously reduce gaps or voids in the first conductive layer 238a and the second conductive layer 238b.

Reference is now made to FIG. 14A, which depicts a cross-sectional view of the workpiece 200 taken along line A-A′. In the cross-sectional view depicted in FIG. 14A, the top surface of the first conductive layer 238a includes a convex top surface and the bottom surface of the first conductive layer 238a tracks the shape of the top surface of the silicide layer 236a. Since the first contact opening 234a exposes the portion 226b of the bottom surface of the CESL 226, and the CESL 226 overhangs the recessed p-type source/drain feature 222P, thus, after the formation of the first conductive layer 238a and the second conductive layer 238b, a portion of the first conductive layer 238a is formed directly under and in direct contact with the portion 226b of the bottom surface of the CESL 226 previously exposed by the second contact opening 234a. As depicted in FIG. 14A, the first conductive layer 238a spans a width D3 along the X direction. The width D3 is less than the width D2 (shown in FIG. 13A). In an embodiment, the width D3 may be between about 10 nm and about 15 nm. A thickness T6 of the first conductive layer 238a (i.e., a distance between a topmost point of the first conductive layer 238a and a bottommost point of the first conductive layer 238a) in a cross-sectional view of the workpiece taken along line A-A′ may be between about 15 nm and about 20 nm. After the formation of the first conductive layer 238a and the second conductive layer 238b, at least a portion of a top surface of the first conductive layer 238a is above the top surface of the p-type source/drain feature 222P. That is, the first conductive layer 238a has a lower portion extending into the p-type source/drain feature 222P and an upper portion protruding from the p-type source/drain feature 222P. A depth T7 of the portion of the first conductive layer 238a that extends into the p-type source/drain feature 222P from the top surface of the fin-shaped active region 204A (i.e., a distance between the bottommost point of the first conductive layer 238a and the top surface 204t of the fin-shaped active region 204A) is between about 5 nm and about 10 nm. A thickness T8 of the portion of the first conductive layer 238a that protrudes from the p-type source/drain feature 222P (i.e., a distance between the topmost point of the first conductive layer 238a and the bottom surface of the CESL 226) is between about 1 nm and about 5 nm.

Reference is now made to FIG. 14B, which depicts a cross-sectional view of the workpiece 200 taken along line B-B′. As depicted in FIG. 14B, the top surface of the first conductive layer 238a includes a substantially flat top surface, and the top surface of the second conductive layer 238b includes a substantially flat top surface. Forming the flat top surface would reduce step coverage of to-be-formed third/fourth conductive layer that would be formed thereover and reduce the extent of extrusion of the to-be-formed third/fourth conductive layer into the source/drain feature and thus reduce contact resistance. In embodiments represented in FIG. 14B, each of the first conductive layer 238a and the second conductive layer 238b has a thickness T6N. Since the first conductive layer 238a and the second conductive layer 238b have flatter top surfaces in the cross-sectional view shown in FIG. 14B than those in the cross-sectional view shown in FIG. 14A, the thickness T6N is less than the thickness T6. In an embodiment, the thickness TON is between about 10 nm and about 15 nm. As depicted in FIG. 14B, the first conductive layer 238a spans a width D3P along the Y direction. In an embodiment, the width D3P may be between about 40 nm and about 45 nm. The second conductive layer 238b spans a width D3N along the Y direction. In an embodiment, the width D3N may be between about 40 nm and about 45 nm. In some embodiments, the width D3N may be greater than the width D2N, and the width D3P may be greater than the width D2P.

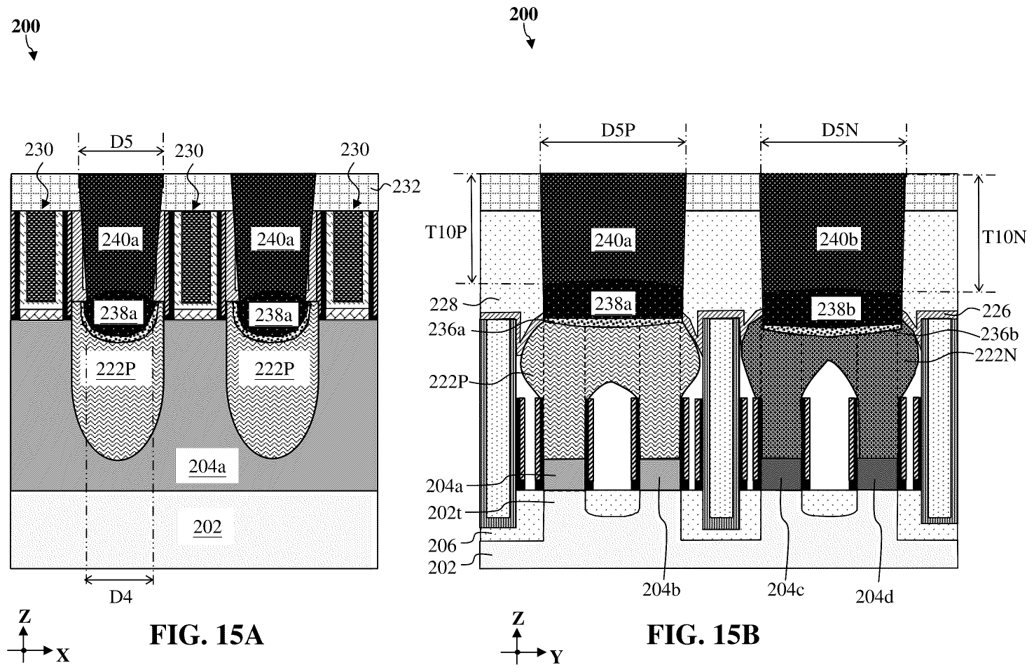

Referring to FIGS. 1 and 15A-15B, method 100 includes a block 126 where a third conductive layer 240a is formed over the first conductive layer 238a and a fourth conductive layer 240b is formed over the second conductive layer 238b to fill the first and second contact openings 234a and 234b, respectively. In embodiments represented in FIGS. 15A and 15B, the third conductive layer 240a is on and in direct contact with the first conductive layer 238a, and is spaced apart from the silicide layer 236a by the first conductive layer 238a. The fourth conductive layer 240b is on and in direct contact with the second conductive layer 238b, and is spaced apart from the silicide layer 236b by the second conductive layer 238b. In an example process, a conductive material layer is deposited, by any suitable processes, over the workpiece 200 to substantially fill the first and second contact openings 234a and 234b. The conductive material layer may include cobalt (Co), ruthenium (Ru), or molybdenum (Mo). In one embodiment, the conductive material layer includes ruthenium (Ru) formed by CVD process. A planarization process, such as a chemical mechanical polish (CMP) process, may be then performed to remove excess portions of the conductive material layer to form the third conductive layer 240a directly on the first conductive layer 238a and the fourth conductive layer 240b directly on the second conductive layer 238b. After the performing of the planarization process, top surfaces of the third conductive layer 240a and the fourth conductive layer 240b are coplanar. Since the depth of the first contact opening 234a is less than the depth of the second contact opening 234b, as depicted in FIG. 15B, a thickness T10N of the fourth conductive layer 240b is greater than a thickness T10P of the third conductive layer 240a. That is, a bottom surface of the third conductive layer 240a is above a bottom surface of the fourth conductive layer 240b. In an embodiment, the thickness T10N may be between about 20 nm and about 25 nm, and the thickness T10P is between about 15 nm and about 20 nm. In an embodiment, a thickness difference between the thickness T10N and the thickness T10P is between about 1 nm and about 5 nm.

In an embodiment, as depicted in FIG. 15A, portions of the first ILD layer 228 and the CESL 226 are interposed between the third conductive layer 240a and the gate spacers 218a. Bottom surfaces of the third conductive layer 240a and the fourth conductive layer 240b track shapes of top surfaces of the first conductive layer 238a and second conductive layer 238b, respectively. That is, bottom surfaces of the third conductive layer 240a and the fourth conductive layer 240b curve upward. As depicted in FIG. 15A, a bottom surface of the third conductive layer 240a spans a width D4 along the X direction. The width D4 is less than the width D3. In some embodiments, a ratio of the width D4 to the width D1 may be between about 0.4 and 0.7. In an embodiment, the width D4 may be between about 8 nm and about 12 nm. A top surface of the third conductive layer 240a spans a width D5 along the X direction. In an embodiment, the width W5 may be between about 20 nm and about 25 nm. In some embodiments, the width W5 may be equal to the width WI of the p-type source/drain feature 222P.

In an embodiment, as depicted in FIG. 15B, an interface between the fourth conductive layer 240b and the second conductive layer 238b is disposed in the first ILD layer 228. As depicted in FIG. 15B, the top surface of the third conductive layer 240a spans a width DSP along the Y direction. The width D5P is less than the width D1P. In an embodiment, the width D5P is between about 45 nm and about 50 nm. The top surface of the fourth conductive layer 240b spans a width D5N along the Y direction. The width D5N is less than the width D1N. In an embodiment, the width D5N is between about 45 nm and about 50 nm.

Referring to FIG. 1, method 100 includes a block 128 where further processes are performed to finish the fabrication of the workpiece 200. Such further processes may include forming a multi-layer interconnect (MLI) structure (not depicted) over the workpiece 200. In some embodiments, the MLI structure may include multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers.

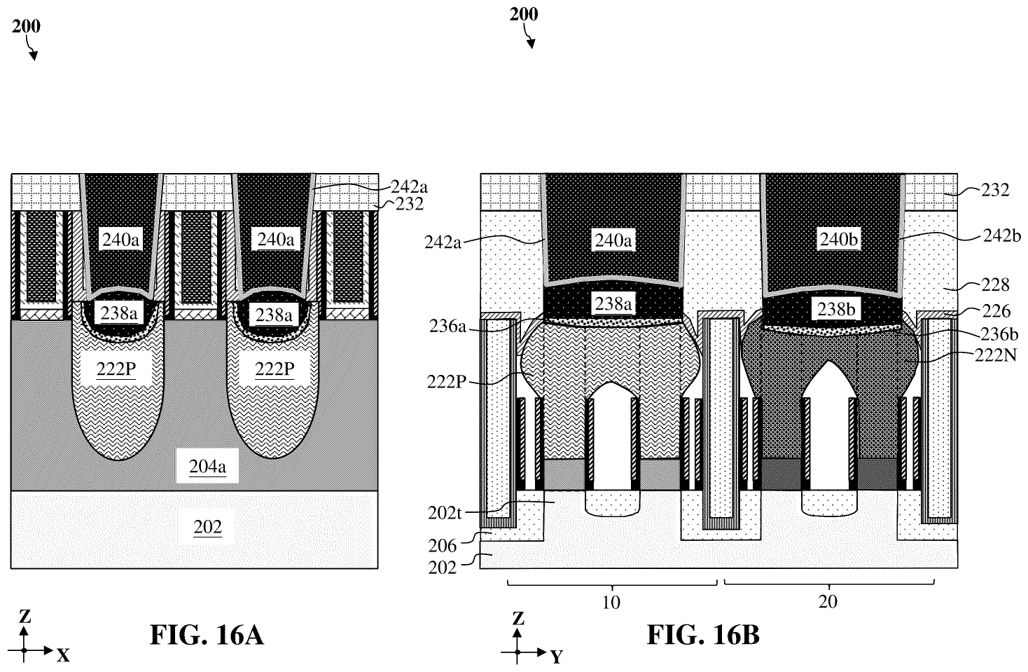

In methods and structures depicted above, the first conductive layer 238a is over and in direct contact with the silicide layer 236a, and the third conductive layer 240a is over and in direct contact with the first conductive layer 238a. Similarly, the second conductive layer 238b is over and in direct contact with the silicide layer 236b, and the fourth conductive layer 240b is over and in direct contact with the second conductive layer 238b. In some alternative embodiments, the workpiece 200 may also include barrier layers. For example, in embodiments represented in FIGS. 16A-16B, the workpiece 200 includes a barrier layer 242a formed in the first contact opening 234a and a barrier layer 242b formed in the second contact opening 234b. In an example process, after forming the first conductive layer 238a and the second conductive layer 238b, a barrier material layer may be conformally deposited over the workpiece 200 by ALD, CVD, or other suitable processes. The conductive material layer for forming the third conductive layer 240a and the fourth conductive layer 240b may be deposited after the deposition of the barrier material layer. A planarization process may be then performed to remove excess portions of the barrier material layer and excess portions of the conductive material layer to define a final structure of source/drain contacts (i.e., including the first/second conductive layer 238a/238b, the barrier layer 242a/242b, and the third/fourth conductive layer 240a/240b) formed in the first and second contact openings 234a-234b. In some embodiments, the barrier material layer may include titanium nitride (TiN), tantalum nitride (TaN), cobalt nitride (CoN), nickel nitride (NiN), manganese nitride (MnN), tungsten nitride (WN), or other transition metal nitride. In one embodiment, the barrier material layer includes titanium nitride (TiN). Since the barrier layer 242a and the barrier layer 242b arc portions of the conformally deposited barrier material layer, a composition and a thickness of the barrier layer 242a is the same as a composition and a thickness of the barrier layer 242b. In the embodiments presented in FIG. 16B, the barrier layer 242a includes a flat portion sandwiched by the first conductive layer 238a and the third conductive layer 240a and a vertical portion extending along a sidewall surface of the third conductive layer 240a. The barrier layer 242b includes a flat portion sandwiched by the second conductive layer 238b and the fourth conductive layer 240b and a vertical portion extending along a sidewall surface of the fourth conductive layer 240b.

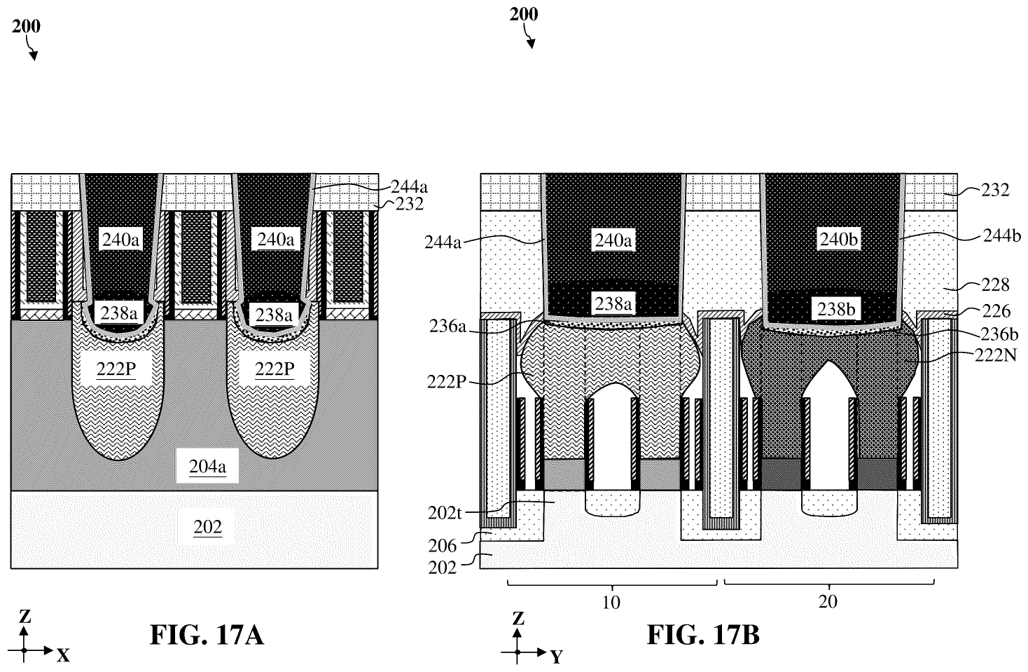

FIGS. 17A-17B depict cross-sectional views of the workpiece 200, according to another alternative embodiment of the present disclosure. In embodiments represented in FIGS. 17A-17B, the workpiece 200 includes barrier layers 244a and 244b. More specifically, the workpiece 200 includes a barrier layer 244a formed in the first contact opening 234a and a barrier layer 244b formed in the second contact opening 234b. In an example process, after forming the silicide layers 236a and 236b, a barrier material layer may be conformally deposited over the workpiece 200 by ALD, CVD, or other suitable processes. The processes for forming the first conductive layer 238a, the second conductive layer 238b, the third conductive layer 240a, and the fourth conductive layer 240b are performed after the deposition of the barrier material layer. A planarization process that is used to remove excess portions of the barrier material layer may be performed before or after the formation of the first conductive layer 238a, the second conductive layer 238b, the third conductive layer 240a, and the fourth conductive layer 240b to define final shapes of the barrier layers 244a-244b and/or source/drain contacts formed in the contact openings 234a-234b. A composition of the barrier layer 244a/244b may be the same as the composition of the barrier layer 242a/242b. In the embodiments presented in FIG. 17B, the barrier layer 244a includes a flat portion sandwiched by the first conductive layer 238a and the silicide layer 236a and a vertical portion extending along sidewall surfaces of the first conductive layer 238a and third conductive layer 240a, and the barrier layer 244b includes a flat portion sandwiched by the second conductive layer 238b and the silicide layer 236b and a vertical portion extending along sidewall surfaces of the third conductive layer 240a and the fourth conductive layer 240b.

Although not intended to be limiting, one or more embodiments of the present disclosure provide many benefits to a semiconductor structure and the formation thereof. For example, one advantage is that, during the formation of the source/drain contact opening, source/drain features are slightly recessed and subsequently formed silicide layers have flat top surfaces. The flat top surface would reduce step coverage of metal formed thereover and reduce contact resistance. Another advantage is that the source/drain contact can be formed to be substantially free of voids or gaps. In an embodiment, to form the source/drain contact, a first deposition process may be a PVD process configured to partially fill the source/drain contact opening without trapping voids in the deposited tungsten layer. The elimination (or at least substantial reduction) of the voids or gaps in the resulting source/drain contact can reduce the parasitic resistance of the source/drain contact, since any trapped air bubble in the source/drain contact would contribute greatly to the parasitic resistance thereof.

The present disclosure provides for many different embodiments. Semiconductor structures and methods of fabrication thereof are disclosed herein. In one exemplary aspect, the present disclosure is directed to a method. The method includes receiving a workpiece comprising a channel region over a substrate, a source/drain feature adjacent the channel region, a gate structure over the channel region, and a dielectric structure over the source/drain feature. The method also includes forming a contact opening penetrating through the dielectric structure to expose the source/drain feature, forming a silicide layer in the contact opening and on the source/drain feature, forming a tungsten-containing layer in the contact opening and on the silicide layer, and forming a conductive layer in the contact opening and on the tungsten-containing layer, where a composition of the conductive layer is different from a composition of the tungsten-containing layer.

In some embodiments, the method may also include, before the forming of the tungsten-containing layer, performing a cleaning process to the silicide layer to remove an oxidized portion of the silicide layer. In some embodiments, the forming of the tungsten-containing layer may include performing a physical vapor deposition (PVD) process, and the forming of the conductive layer may include performing a chemical vapor deposition (CVD) process. In some embodiments, the tungsten-containing layer may include tungsten (W), and the conductive layer may include ruthenium (Ru), molybdenum (Mo), or cobalt (Co). In some embodiments, the silicide layer may include a concave top surface in a first cross-sectional view cut through the gate structure and the source/drain feature and may include a substantially flat top surface in a second cross-sectional view cut through the source/drain feature without cutting through the gate structure. In some embodiments, in the first cross-sectional view, the tungsten-containing layer may include a convex top surface, and a topmost point of the convex top surface of the tungsten-containing layer may be above a topmost point of a top surface of the source/drain feature. In some embodiments, in the second cross-sectional view, a thickness of the silicide layer is not uniform. In some embodiments, in the first cross-sectional view, a lower portion of the tungsten-containing layer may extend into the source/drain feature and an upper portion of the tungsten-containing layer may be above the source/drain feature, and an entirety of the conductive layer may be above the source/drain feature. In some embodiments, a portion of the tungsten-containing layer may be in direct contact with a portion of a bottom surface of the dielectric structure.

In another exemplary aspect, the present disclosure is directed to a method. The method includes receiving a workpiece comprising a first region and a second region, the workpiece comprising a first gate structure over channel regions of a first fin and a second fin over the first region, a p-type source/drain feature disposed and spanning over the first fin and the second fin, a second gate structure over channel regions of a third fin and a fourth fin over the second region, an n-type source/drain feature disposed and spanning over the first fin and the second fin over the second region, and a dielectric structure over the p-type source/drain feature and the n-type source/drain feature. The method also includes forming a first contact opening extending through the dielectric structure to expose the p-type source/drain feature and a second contact opening extending through the dielectric structure to expose the n-type source/drain feature, performing a first deposition process to form a first conductive layer in the first contact opening and a second conductive layer in the second contact opening, and performing a second deposition process to form a third conductive layer over first conductive layer and a fourth conductive layer over the second conductive layer, the first deposition process is different than the second deposition process, and a composition of the first and second conductive layers is different than a composition of the third and fourth conductive layers.

In some embodiments, the first deposition process may include a physical vapor deposition (PVD) process, and the second deposition process may include a chemical vapor deposition (CVD) process. In some embodiments, the first and second conductive layers may include tungsten (W), and the third and fourth conductive layers may include ruthenium (Ru), molybdenum (Mo), or cobalt (Co). In some embodiments, a depth of the first contact opening may be less than a depth of the second contact opening. In some embodiments, a thickness of the third conductive layer may be less than a thickness of the fourth conductive layer. In some embodiments, the method may also include, before the performing of the first deposition process, forming a first silicide layer in the first contact opening and forming a second silicide layer in the second contact opening, and in a cross-sectional view, a top surface of the first silicide layer and a top surface of the second silicide layer may be substantially flat. In some embodiments, the method may also include, after the performing of the first deposition process and before the performing of the second deposition process, forming a barrier layer in the first and second contact openings and over the first and second conductive layers.

In yet another exemplary aspect, the present disclosure is directed to a semiconductor structure. The semiconductor structure includes a gate structure over channel regions of a first fin and a second fin, a source/drain feature disposed and spanning over the first fin and the second fin, a dielectric layer over the source/drain feature, and a source/drain contact extending through the dielectric layer to electrically couple to the source/drain feature, where the source/drain contact includes a first conductive layer over the source/drain feature and a second conductive layer over the first conductive layer, a composition of the first conductive layer is different than a composition of the second conductive layer, and, in a first cross-sectional view cut through the gate structure and the source/drain feature, a bottom surface of the second conductive layer is above a top surface of the source/drain feature.

In some embodiments, a portion of the first conductive layer may extend into the source/drain feature, and the first conductive layer may include a convex top surface. In some embodiments, the semiconductor structure may also include gate spacers extending along sidewall surfaces of the first gate structure, a portion of the dielectric layer may be interposed between the source/drain contact and the gate spacers. In some embodiments, the semiconductor structure may also include a silicide layer on the source/drain feature, where the silicide layer may include a concave top surface in the first cross-sectional view and a substantially flat top surface in a second cross-sectional view different from the first cross-sectional view.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a source/drain feature;
an interlayer dielectric (ILD) layer disposed over the source/drain feature;
a source/drain contact disposed in the ILD layer to electrically couple to the source/drain feature;
a metal silicide layer disposed between the source/drain feature and the source/drain contact, wherein the metal silicide layer comprises a curved top surface in a cross-sectional view, and
wherein the source/drain contact comprises a first layer and a second layer over the first layer, the second layer is spaced apart from the metal silicide layer by the first layer, the first layer and the second layer comprises different compositions, and in the cross-sectional view, a bottom surface of the second layer is above a topmost surface of the metal silicide layer.

2. The semiconductor structure of claim 1, further comprising:
a barrier layer disposed between the first layer and the second layer.

3. The semiconductor structure of claim 2, wherein the barrier layer further extends along a sidewall surface of the second layer and disposed between the second layer and the ILD layer.

4. The semiconductor structure of claim 1, further comprising:
a contact etch stop layer (CESL) disposed between the ILD layer and the source/drain feature,
wherein a portion of the first layer is disposed under and vertically overlapped with the CESL.

5. The semiconductor structure of claim 1, wherein the first layer comprises a convex top surface in the cross-sectional view.

6. The semiconductor structure of claim 1, wherein the cross-sectional view is a first cross-sectional view, the first layer has a first thickness in the first cross-sectional view and a second thickness in a second cross-sectional view different from the first cross-sectional view, wherein the second thickness is less than the first thickness.

7. The semiconductor structure of claim 1, wherein the first layer comprises tungsten, and the second layer comprises ruthenium (Ru), molybdenum (Mo), or cobalt (Co).

8. The semiconductor structure of claim 1, further comprising:
a first fin and a second fin protruding from a substrate,
wherein the source/drain feature extends from both the first fin and the second fin.

9. The semiconductor structure of claim 1, further comprising:
an isolation structure disposed adjacent to the source/drain feature,
wherein a topmost surface of the source/drain feature is above a top surface of the isolation structure.

10. A semiconductor structure, comprising:
a first type of source/drain feature and a second type of source/drain feature;
a first metal contact and a second metal contact disposed above the first type of source/drain feature and the second type of source/drain feature, respectively;
a first silicide layer between the first type of source/drain feature and the first metal contact; and
a second silicide layer between the second type of source/drain feature and the second metal contact, wherein a composition of the first silicide layer is different from a composition of the second silicide layer, and wherein in a cross-sectional view cut through the first type of source/drain feature and the second type of source/drain feature, a bottom surface of the first silicide layer is above a bottom surface of the second silicide layer.

11. The semiconductor structure of claim 10, wherein in the cross-sectional view, the bottom surface of the first silicide layer is substantially flat.

12. The semiconductor structure of claim 10, wherein in the cross-sectional view, the bottom surface of the second silicide layer is a curved surface.

13. The semiconductor structure of claim 10, wherein the first metal contact comprises:
a first metal layer extending over the first silicide layer; and
a second metal layer over the first metal layer and spaced apart from the first silicide layer, wherein the first metal layer and the second metal layer comprise different compositions.

14. The semiconductor structure of claim 13, wherein the cross-sectional view is a first cross-sectional view, and in a second cross-sectional view different from the first cross-sectional view, the first metal layer comprises a first portion wrapped around by the first silicide layer and a second portion protruding from the second portion.

15. The semiconductor structure of claim 13, further comprising:
a barrier layer extending between the first metal layer and the second metal layer.

16. The semiconductor structure of claim 15, wherein the barrier layer further extends along a sidewall surface of the second metal layer.

17. A semiconductor structure, comprising:
an active region disposed over a substrate;
an epitaxial feature disposed over a source/drain region of the active region and comprising a dopant, wherein the epitaxial feature comprises a first layer and a second layer, wherein a concentration of the dopant in the first layer varies from a concentration of the dopant in the second layer;
an isolation structure disposed adjacent to the epitaxial feature, wherein a top surface of the epitaxial feature is above a top surface of the isolation structure;
an interlayer dielectric (ILD) layer disposed over the epitaxial feature; and
a source/drain contact extending through the ILD layer to electrically couple to the epitaxial feature, wherein an electrical conductivity of the source/drain contact is greater than an electrical conductivity of the epitaxial feature, wherein the source/drain contact comprises:
a lower portion formed of a first composition, wherein the lower portion comprises a convex top surface, and
an upper portion formed of a second composition different from the first composition.

18. The semiconductor structure of claim 17, further comprising:
a silicide layer disposed between the epitaxial feature and the lower portion of the source/drain contact, where the silicide layer comprises a concave top surface and a concave bottom surface.

19. The semiconductor structure of claim 18, wherein, in a cross-sectional view, an entirety of the convex top surface of the lower portion of the source/drain contact is above a topmost surface of the silicide layer.

20. The semiconductor structure of claim 17, further comprising:
a continuous barrier layer extending along a sidewall surface of the upper portion of the source/drain contact and a bottom surface of the upper portion of the source/drain contact.
